(19) United States
(12) Patent Application Publication
(10) Pub. No.: US 2025/0372545 A1
(43) Pub. Date: Dec. 4, 2025

(54) HETEROGENEOUS INTEGRATION STRUCTURE TO SOLVE IVR OVERSHOOT PROBLEM

(71) Applicant: Taiwan Semiconductor Manufacturing Co., Ltd., Hsinchu (TW)

(72) Inventors: Yen-Ming Chen, Chu-Pei City (TW); Chuei-Tang Wang, Taichung City (TW); Shu An Shang, Hsinchu (TW); Yu-Ming Hsiao, Hsinchu (TW)

(21) Appl. No.: 18/890,176

(22) Filed: Sep. 19, 2024

Related U.S. Application Data
(60) Provisional application No. 63/654,353, filed on May 31, 2024.

(51) Int. Cl. H01L 23/62; H01L 23/00; H01L 23/31; H01L 23/498; H01L 23/64; H01L 25/18

(52) U.S. Cl. CPC H01L 23/62; H01L 23/3128; H01L 23/49816; H01L 23/49827; H01L 23/642; H01L 24/16; H01L 24/24; H01L 24/73; H01L 25/18; H01L 2224/16225; H01L 2224/24226; H01L 2224/73204; H01L 2924/1205; H01L 2924/1207

(57) ABSTRACT

A method includes placing an integrated voltage regulator in a first package component, placing a RC component in a second package component, electrically connecting the RC component to the integrated voltage regulator, and electrically connecting a device die to the RC component. The RC component is in an electrical path that connects the integrated voltage regulator to the device die.

### PRIORITY CLAIM AND CROSS-REFERENCE

This application claims the benefit of the following provisionally filed U.S. Patent application: Application No. 63/654,353, filed on May 31, 2024, and entitled “HETEROGENEOUS INTEGRATION STRUCTURE TO SOLVE IVR OVERSHOOT PROBLEM,” which application is hereby incorporated herein by reference.

### BACKGROUND

Voltage regulators are used in integrated circuits to provide power. The voltage regulators have the ability of regulating power supply voltages. In a package, the voltage regulators may be formed as discrete dies, which are bonded to a printed circuit board. The voltages generated by the voltage regulators are provided to the integrate circuit components that are also bonded to the printed circuit board.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1-9 illustrate the cross-sectional views of intermediate stages in the formation of a package including an Integrated Voltage Regulator (IVR) and a Resistor-Capacitor (RC) component in accordance with some embodiments.

FIG. 10 illustrates an amplified view of a portion of a package in accordance with some embodiments.

FIGS. 11 and 12 illustrate a package and an amplified portion, respectively, of the package in accordance with some embodiments.

FIGS. 13 and 14 illustrate a package and an amplified portion, respectively, of the package in accordance with some embodiments.

FIG. 15-18 illustrate some packages including IVRs and RC components in accordance with some embodiments.

FIGS. 19 and 20 illustrate the circuit diagrams of IVRs and RC components in accordance with some embodiments.

FIG. 21 illustrates an effect of the IVRs and RC components in packages in accordance with some embodiments.

FIG. 22 illustrates a process flow for forming a package in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “underlying,” “below,” “lower,” “overlying,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

A package including an Integrated Voltage Regulator (IVR) and a Resistor-Capacitor (RC) component and the method of forming the same are provided. In accordance with some embodiments of the present disclosure, an IVR and a RC component are embedded in a package. The IVR and the RC component may be embedded in a core of a package substrate, a build-up structure of a package substrate, an underfill, a redistribution structure, a layer for allocating Local Silicon Interconnect (LSI) dies, and/or the like. The RC component is located close to the IVR. Furthermore, the RC component may be located in the path between the IVR and the powered devices powered by the regulated voltages, so that the resistance of the connection lines may be reduced. By adopting the IVR and the RC component, the transient overshoot of the IVR may be reduced.

Embodiments discussed herein are to provide examples to enable making or using the subject matter of this disclosure, and a person having ordinary skill in the art will readily understand modifications that can be made while remaining within contemplated scopes of different embodiments. Throughout the various views and illustrative embodiments, like reference numbers are used to designate like elements. Although method embodiments may be discussed as being performed in a particular order, other method embodiments may be performed in any logical order.

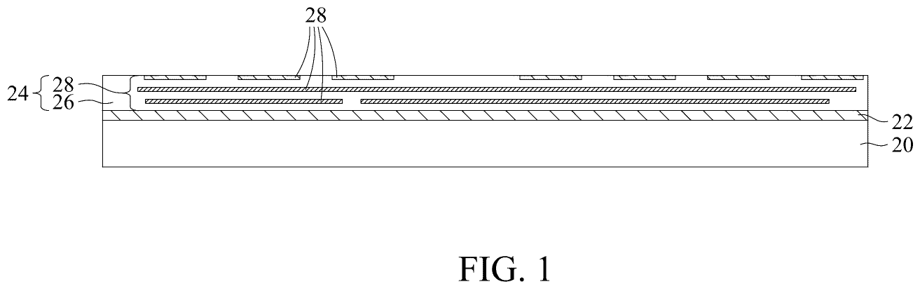

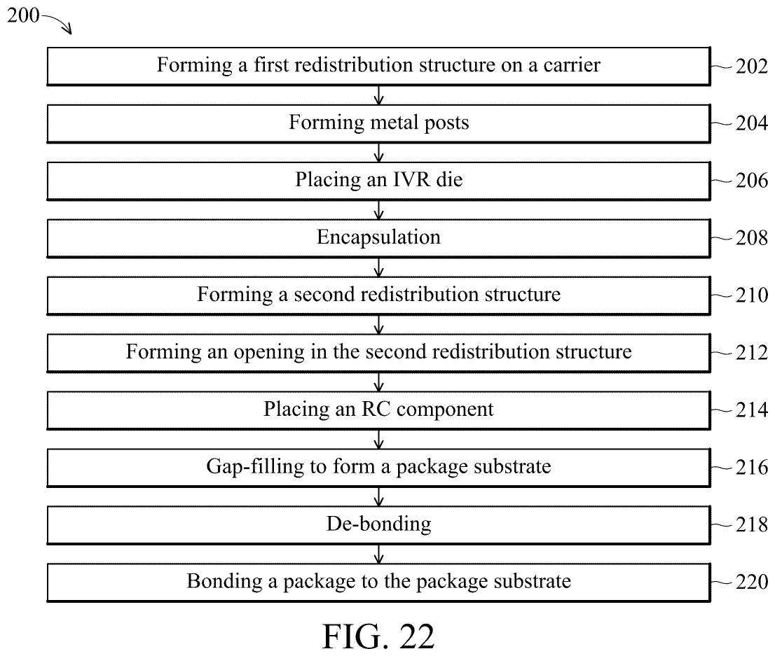

FIGS. 1 through 9 illustrate the views of intermediate stages in the formation of a package including an IVR and a RC component in accordance with some embodiments of the present disclosure. The corresponding processes are also reflected schematically in the process flow shown in FIG. 22.

FIG. 1 illustrates carrier 20 and release film 22 formed on carrier 20. Carrier 20 may be a glass carrier, a silicon wafer, an organic carrier, or the like. Release film 22 may be formed of a polymer-based material (such as a Light-To-Heat-Conversion (LTHC) material), which is capable of being decomposed under heat-carrying radiation such as a laser beam, so that carrier 20 may be de-bonded from the overlying structures that will be formed in subsequent processes.

A build-up structure 24 (also referred to as redistribution structure 24 or interconnect structure 24) is formed over carrier 20. The respective process is illustrated as process 202 in the process flow 200 as shown in FIG. 22. The build-up structure 24 includes a plurality of dielectric layers 26 and a plurality of Redistribution Lines (RDLs) 28 formed over the release film 22. Dielectric layers 26 may be formed of a polymer(s), which may also be a photo-sensitive material(s) such as polybenzoxazole (PBO), polyimide, benzocyclobutene (BCB), or the like, that may be patterned using a photo-lithography process including a light-exposure process and a development process.

RDLs 28 may be formed through plating. The formation of RDLs 28 may include forming a metal seed layer (not shown), forming a patterned mask (not shown) such as a photoresist over the metal seed layer, and then performing a metal plating process on the exposed seed layer. The patterned mask and the portions of the metal seed layer covered by the patterned mask are then removed, leaving RDLs 28. In accordance with some embodiments, the metal seed layer includes a titanium layer and a copper layer over the titanium layer. The metal seed layer may be formed using, for example, Physical Vapor Deposition (PVD) or a like process. The plating may be performed using, for example, an electrochemical plating process or an electro-less plating process. The plated material may comprise copper.

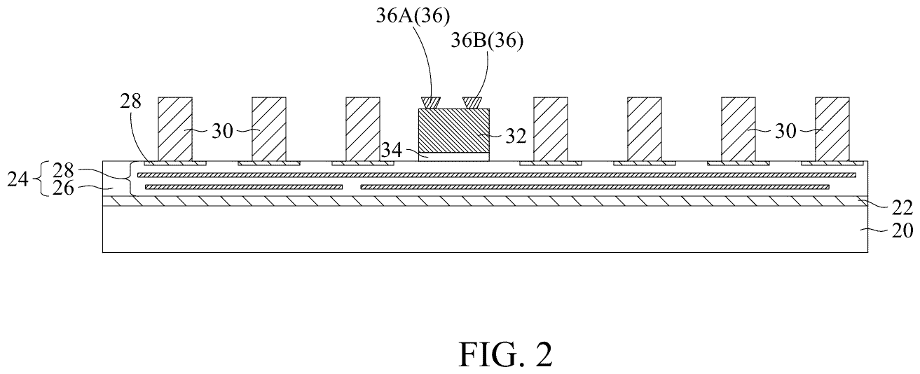

Next, as shown in FIG. 2, metal posts 30 are formed. The respective process is illustrated as process 204 in the process flow 200 as shown in FIG. 22. The formation process may include forming a metal seed layer, forming a plating mask (not shown, may be a photoresist) over the metal seed layer, patterning the plating mask to reveal the underlying metal seed layer, and then plating a metallic material in the openings of the plating mask. The plating mask is then removed, followed by an etching process to remove the portions of the metal seed layer previously covered by the plating mask.

Metal posts 30 are alternatively referred to as through-vias since they will penetrate through the subsequently formed encapsulating material (which may be a molding compound). The plated metallic material may be copper or a copper alloy. Metal posts 30 may have substantially vertical and straight edges. In accordance with alternative embodiments, conductive pipes (also referred to as Plated Through-Holes (PTHs)) are formed. The formation of the PTHs may be essentially the same as the formation of metal posts 30.

FIG. 2 further illustrates the placement/attachment of IVR die 32. The respective process is illustrated as process 206 in the process flow 200 as shown in FIG. 22. IVR die 32 may be attached to redistribution structure 24, for example, through die-attach film 34, which is an adhesive film. IVR die 32 includes electrical connectors 36A and 36B (collectively referred to as electrical connectors 36), which may include an input node and an output node. Electrical connectors 36A and 36B may be metal pillars in accordance with some embodiments.

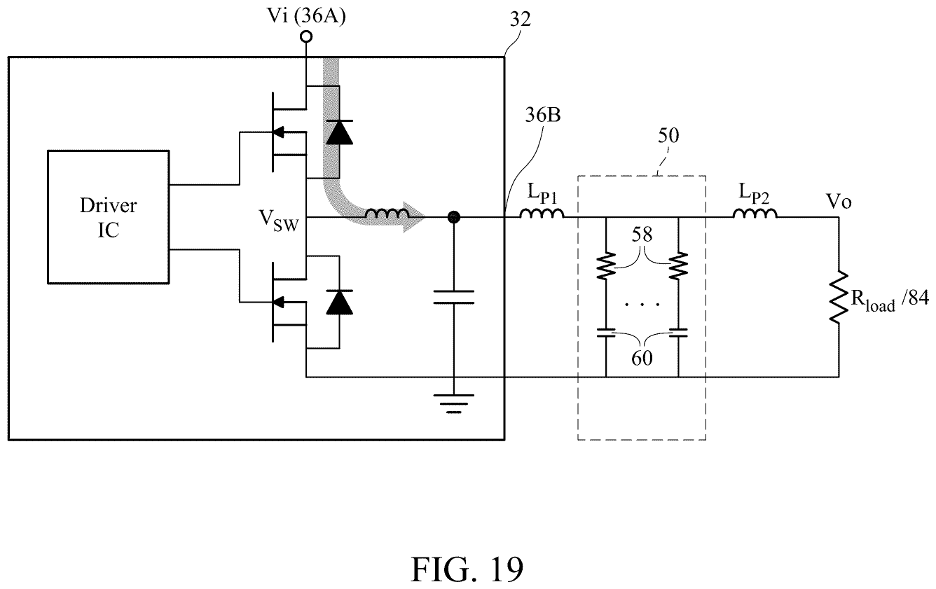

FIG. 19 illustrates the circuit diagram of an example IVR die 32 in accordance with some embodiments. The input node 36A of IVR die 32 is used for receiving a high input voltage Vi, such as 15 V, 9V, or the like input voltage Vi is also shown in FIG. 2 in accordance with some embodiments. Through the drive IC and other circuits, other power supply voltages such as 5V, 3.3V, 1.2V, 0.9V, and 0.75V, and/or the like, are generated at output node(s) 36B, which are also the electrical connector(s) 36B in FIG. 2 in accordance with some embodiments.

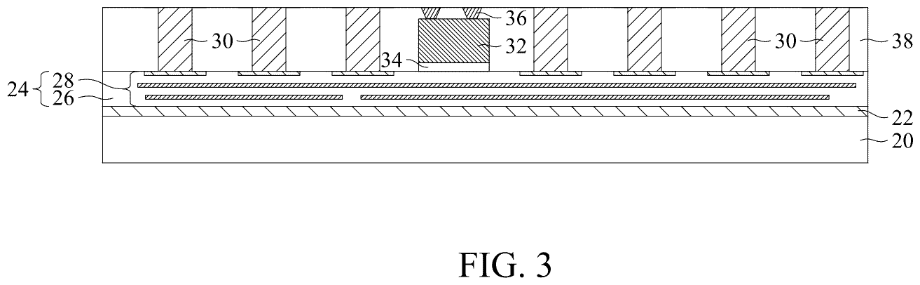

Next, referring to FIG. 3, IVR die 32 and metal posts 30 are encapsulated in encapsulant 38. The respective process is illustrated as process 208 in the process flow 200 as shown in FIG. 22. Encapsulant 38 fills the gaps between neighboring metal posts 30 and IVR die 32. Encapsulant 38 may include glass fiber, prepreg (which comprises epoxy, resin, and/or glass fiber), resin coated Copper (RCC), glass, plastic (such as PolyVinylChloride (PVC), Acrylonitril, Butadiene & Styrene (ABS), Polypropylene (PP), Polyethylene (PE), PolyStyrene (PS), Polymethyl Methacrylate (PMMA), Polyethylene Terephthalate (PET), Polycarbonates (PC), Polyphenylene sulfide (PPS), flex (polyimide), molding compound, molding underfill, epoxy, resin, or combinations thereof.

When formed of a molding compound, encapsulant 38 may include a base material, which may be a polymer, a resin, an epoxy, or the like, and filler particles in the base material. The filler particles may be the dielectric particles of SiO₂, Al₂O₃, silica, or the like, and may have spherical shapes. Also, the spherical filler particles may have a plurality of different diameters.

A planarization process such as a Chemical Mechanical Polish (CMP) process or a mechanical grinding process is then performed to thin encapsulant 38, until metal posts 30 and IVR die 32 are exposed. Due to the planarization process, the top ends of through-vias 30 are substantially level (coplanar) with the top surfaces of electrical connectors 36, and are substantially coplanar with the top surface of encapsulant 38. Throughout the description, metal posts 30 are also referred to as through-vias 30 since they penetrate through encapsulant 38. Encapsulant 38 acts as the dielectric core (and is also referred to as dielectric core 38) in the respective package substrate.

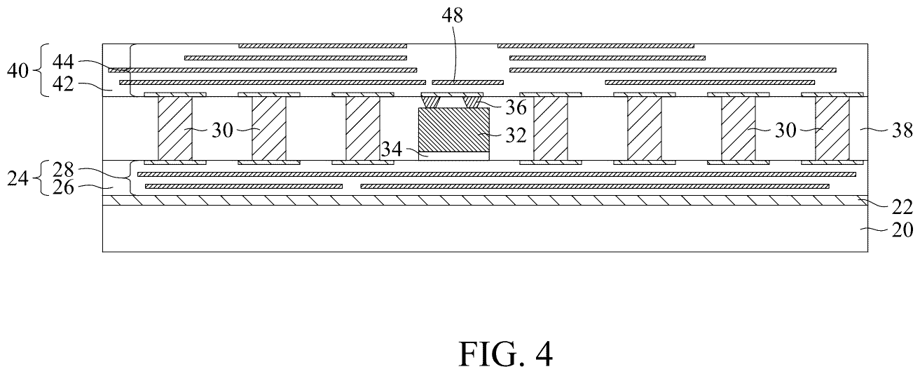

FIG. 4 illustrates the formation of redistribution structure 40 (also referred to as an interconnect structure), which includes dielectric layers 42 and RDLs 44. The respective process is illustrated as process 210 in the process flow 200 as shown in FIG. 22. Redistribution structure 40 is alternatively referred to as build-up structure 40 or interconnect structure 40. The formation of redistribution structure 40 may be essentially the same as that of redistribution structure 24. Dielectric layers 42 may be formed of an organic material such as PBO, polyimide, or the like.

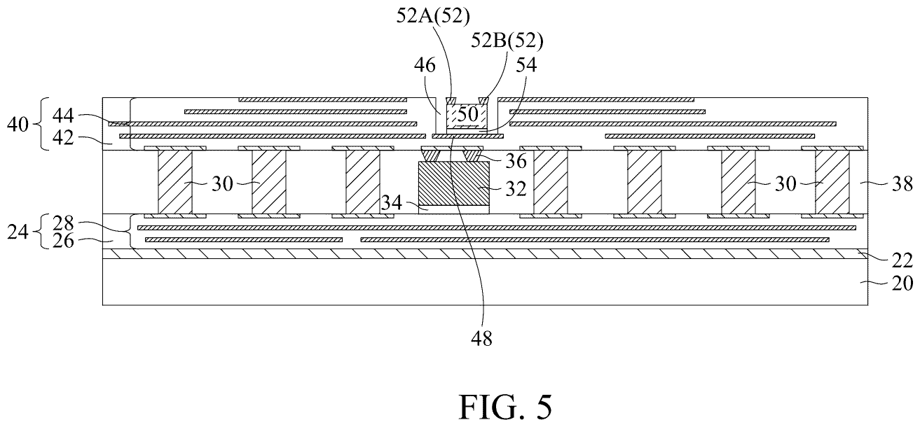

Referring to FIG. 5, opening 46 is formed in the dielectric layers 42 in redistribution structure 40. The respective process is illustrated as process 212 in the process flow 200 as shown in FIG. 22. In accordance with some embodiments, the formation process may include an etching process, in which an etching mask (such as a photoresist) is formed to define the size and the position of opening 46. In accordance with alternative embodiments, the formation of opening 46 includes a laser ablation process. A metal pad 48 may be formed as an etch stop layer (or the stop layer for the laser ablation). The metal pad 48 is also formed in the same processes in which a corresponding layer of RDLs 44 is formed. The metal pad 48 may be electrically floating, or may have electrical connection function, for example, with currents flowing through.

In accordance with alternative embodiments, opening 46 penetrates through dielectric layers 42, with a top surface of encapsulant 38 being exposed and used as the etch stop layer.

FIG. 5 also illustrates the placement of RC component 50 inside opening 46. The respective process is illustrated as process 214 in the process flow 200 as shown in FIG. 22. In accordance with some embodiments, the placement is achieved by using die-attach film 54, which adheres RC component 50 to metal pad 48. In accordance with alternative embodiments, the opening 46 is formed so that RC component 50 may be tightly fit in opening 46, with the sidewalls of RC component 50 in physical contact with the sidewalls of dielectric layers 42. The sidewalls of RC component 50 may be spaced apart from, or may be in physical contact with RDLs 44 in accordance with some embodiments. RC component 50 may include electrical connectors 52 (including 52A and 52B), for example.

RC component 50 may have various structures. For example, FIG. 19 illustrates that RC component 50 may include a plurality of resistors 58 and a plurality of capacitors 60. A resistor 58 and a capacitor 60 may form a unit, and the RC component 50 may include a plurality of units that are connected in parallel.

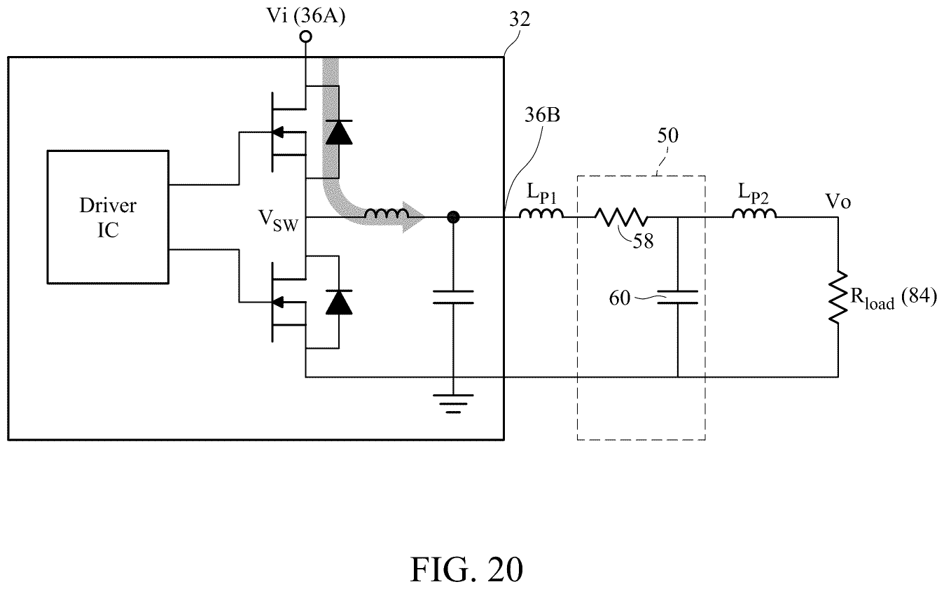

FIG. 20 illustrates a single-RC RC component 50 that includes a single resistor 58 and a single capacitor 60 in accordance with some embodiments. It is appreciated that the IVR 32 and RC component 50 may have many applicable forms other than illustrated in FIGS. 19 and 20, and the corresponding IVR 32 and RC components 50 are also in the scope of the present disclosure.

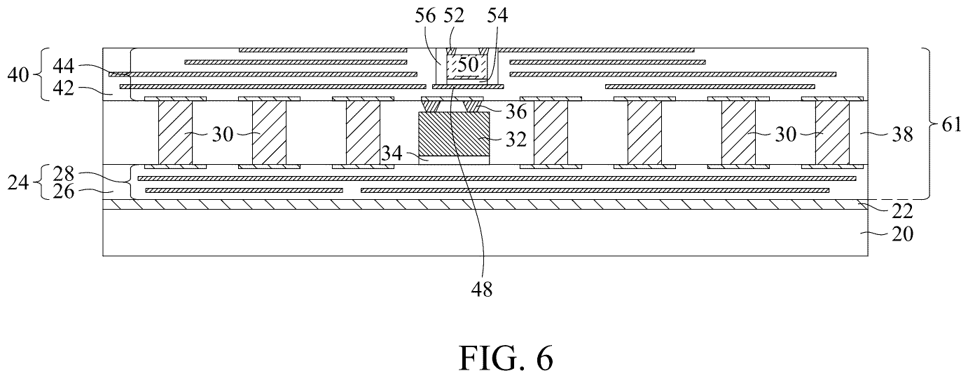

In accordance with some embodiments, as shown in FIG. 6, gap-filling region 56 is formed to fill the rest of opening 46. The respective process is illustrated as process 216 in the process flow 200 as shown in FIG. 22. In accordance with some embodiments, gap-filling region 56 is formed of or comprise an underfill, a polymer, a resin, an epoxy, or the like. The gap-filling region 56 is dispensed into opening 46 and then cured as a solid after the dispensing, followed by a planarization process to level its top surface with the top surface of redistribution structure 40 and electrical connectors 52. Gap-filling region 56 is in physical contact with dielectric layers 42, and may or may not be in physical contact with some of the RDLs 44 on the opposing sides of gap-filling region 56. Gap-filling region 56 may also be in physical contact with the top surface of metal pad 48 in accordance with some embodiments.

The structure over release film 22 is referred to as a (wafer-level) package substrate 61 in accordance with some embodiments, which may include one or a plurality of package substrates therein. In accordance with some embodiments, package substrate 61 may be de-bonded from carrier 20. The respective process is illustrated as process 218 in the process flow 200 as shown in FIG. 22. The de-bonding process may include projecting a radiation (such as a laser beam) on release film 22, which laser beam penetrates through carrier 20. Release film 22 is thus decomposed, and package substrate 61 may be de-bonded from carrier 20.

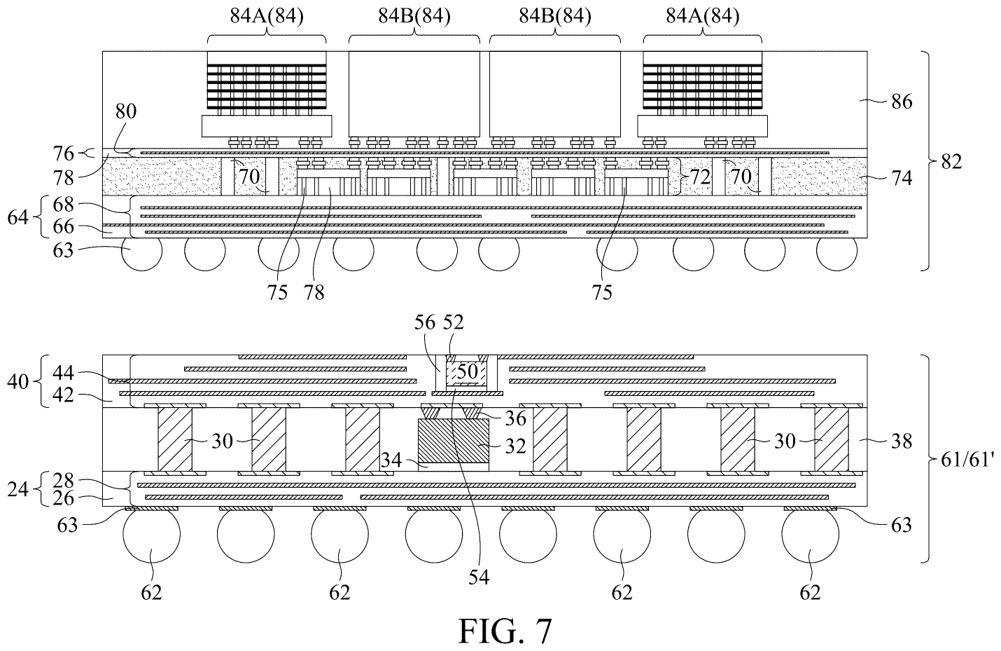

In accordance with some embodiments, as shown in FIG. 7, under-bump metallurgies 63 and solder regions 62 and may be formed on the bottom side of package substrate 61. One of solder regions 62 is electrically connected to IVR die 32 in order to provide the input voltage to IVR die 32. Package substrates 61 may include a plurality of identical package substrates 61′ therein, each including an IVR die 32 and a RC component 50.

In accordance with alternative embodiments, the de-bonding of package substrate 61 from carrier 20 may be performed in a subsequent process, for example, at a time after package component 82 (also referred to as a package) has been bonded to package substrate 61.

In accordance with some embodiments, the package substrate 61 may be singulated in a sawing process, so that the plurality of discrete package substrates 61′ therein are separated from each other. In accordance with alternative embodiments, the sawing of package substrate 61 into discrete package substrates 61′ may be performed in a subsequent process, for example, after a plurality of package components 82 have been bonded to package substrates 61′.

FIG. 7 further illustrates package component 82 (also referred to as a package) in accordance with some embodiments. The formation of package component 82 may include forming redistribution structure 64, which includes a plurality of dielectric layers 66 and redistribution lines 68. The materials and the formation processes of the dielectric layers 66 and the redistribution lines 68 may be essentially the same as that of the dielectric layers 26 and the redistribution lines 28, respectively, in redistribution structure 24. Solder regions 63 may be formed underlying and electrically connected to the redistribution lines 68.

Through-vias 70 are formed over and electrically connecting to the redistribution lines 68. The formation process may be essentially the same as that of through-vias 30, which formation process may include plating through-vias 70 directly from the metal pads in redistribution lines 68.

In accordance with some embodiments, device dies 72 are bonded to redistribution structure 64. Device dies 72 may include LSI dies, which are used to electrically interconnect the overlying package components 84. Device dies 72 may also include passive device dies such as deep-trench capacitor dies. In accordance with some embodiments, the LSI dies include semiconductor substrate 78, and through-substrate vias (TSV, also referred to as through-silicon vias) 76. The TSVs 76 and through-vias 70 electrically connect the redistribution lines 68 to the overlying redistribution lines 80.

Through-vias 70 and device dies 72 are encapsulated in encapsulant 74, which may include molding compound, molding underfill, or may include inorganic materials such as a silicon nitride layer and a silicon oxide region over the silicon nitride layer.

Package component 82 may further include redistribution structure 76 over device dies 72. Redistribution structure 76 may include a plurality of dielectric layers 78 and a plurality of redistribution lines 80. The materials and the formation processes of the dielectric layers 78 and the redistribution lines 80 may be essentially the same as that in redistribution structure 24.

Package components 84 (including package components 84A and 84B) are bonded to redistribution structure 76. The respective process is illustrated as process 220 in the process flow 200 as shown in FIG. 22. The bonding of package components 84 to redistribution structure 76 may be performed through solder bonding, metal-to-metal direct bonding, hybrid bonding (including both of metal-to-metal direct bonding and fusion bonding), or the like.

Package components 84A (also referred to as device dies when including device dies therein) may be High-bandwidth memory (HBM) stacks. Package components 84B may be discrete device dies, System-on-Chip (SoC) dies, or the like. Package components 84B may also include Deep-Trench Capacitors (DTCs), active device dies, Independent Passive Devices (IPDs).

In accordance with some embodiments, package components 84 may be encapsulated in encapsulant 86, which may include a molding compound, a molding underfill or the like. There may also be underfills in the gaps between the package components 84 and the underlying redistribution structure 76.

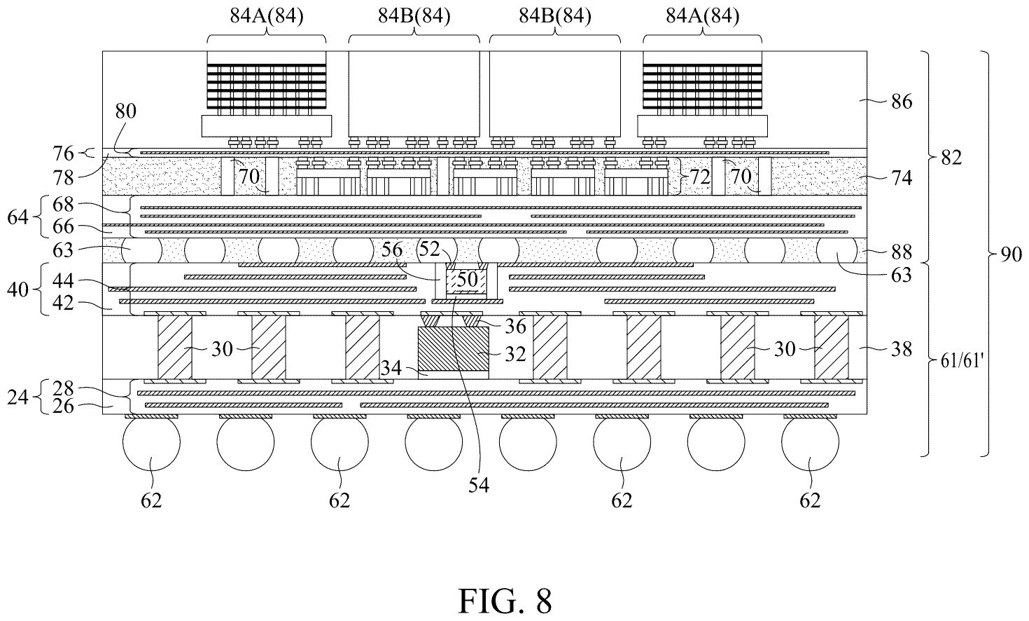

FIG. 8 illustrates the bonding of package component 82 (also referred to as a package) to package substrate 61′ in accordance with some embodiments. Package 90 is thus formed. The bonding may be achieved through solder bonding using solder regions 63. Underfill 88 is also dispensed in the gap between package substrate 61′ and package component 82.

In accordance with some embodiments in which package substrate 61′ has already been sawed into package substrate 61, a die-on-die bonding is performed, and a single package component 82 may be bonded to a discrete package substrate 61′. In accordance with these embodiments, the edges of the single package component 82 may extend laterally beyond the corresponding edges of the package substrate 61′, vertically aligned to the corresponding edges of the package substrate 61′, or laterally recessed from the corresponding edges of the package substrate 61′.

In accordance with alternatively embodiments, a die-on-wafer bonding process is performed, in which a plurality of package components 82 are bonded to the package substrate 61 (including a plurality of package substrates 61′ that have not been sawed apart) that is at the wafer level. After the plurality of package components 82 are bonded to the package substrate 61, an additional encapsulating process may be performed to encapsulate the plurality of package components 82 in an additional encapsulant 86, which additional encapsulant is over and physically contacting the wafer-level package substrate 61. A sawing process is then performed to saw the resulting package into a plurality of identical packages, each including one package substrate 61′ and one package component 82.

In accordance with the embodiments in which the die-on-wafer bonding is performed, the edges of the package component 82 are laterally recessed from the corresponding edges of the underlying package substrate 61′. The outer edges of the additional encapsulant (not shown) are vertically aligned to the edges of the underlying package substrate 61′.

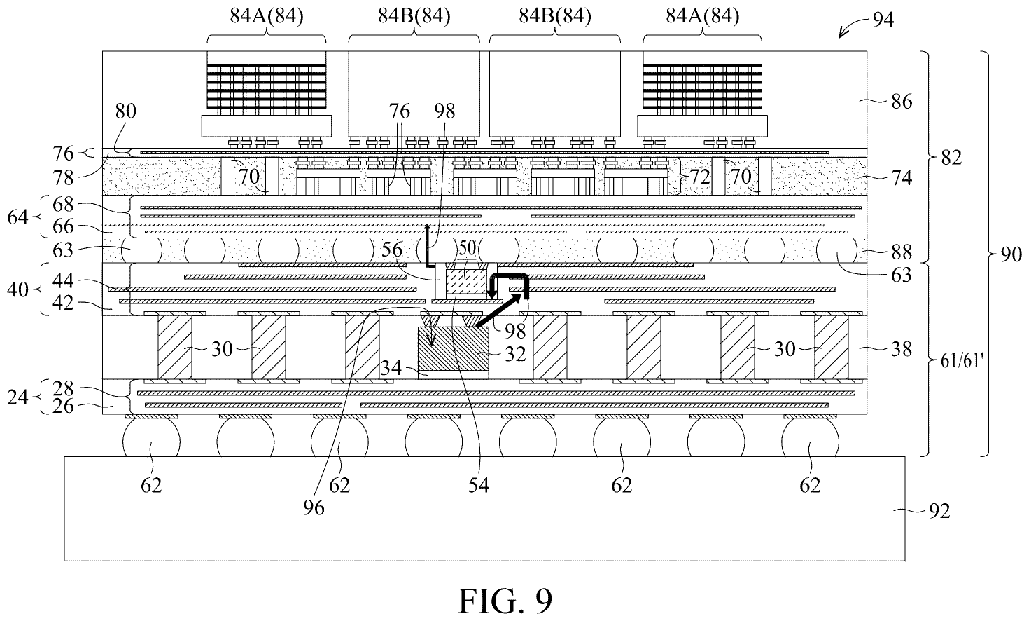

FIG. 9 illustrates the bonding of package 90 to package component 92 to form package 94. Package component 92 may include a printed circuit board, another package substrate, or the like. In the resulting package 94, the input voltage, which may be a relatively high voltage, may be provided from package component 92 into package substrate 61′. The voltage input path from package component 92 into IVR die 32 is illustrated by arrow 96 in accordance with some embodiments.

Arrows 98 illustrate the voltage conduction path of the output voltage from IVR die 32 to powered devices, which include package components 84 in accordance with some embodiments. The output voltage(s), which may be 3.3V, 1.2V, 0.9V, and 0.75V, and/or the like are conducted through redistribution lines 44 to RC component 50, and further conducted to solder regions 63 and redistribution lines 68. Through through-vias 70 and/or TSVs 76 in device dies 74, the output voltages are further conducted to redistribution lines 80, and to package components 84.

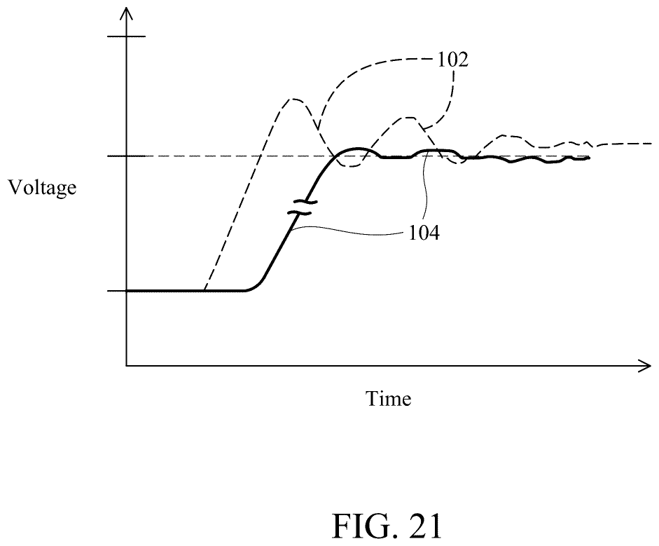

In accordance with some embodiments, due to the insertion of RC component 50 into the path between IVR die 32 and package components 84, the transient overshoot of the IVR output is reduced. For example, FIG. 21 illustrates the output voltages of IVRs as a function of time. Line 102 illustrates the voltage transient before it reaches stable state when the IVR die 32 is not connected to RC component 50. Line 104 illustrates the voltage transient before it reaches stable state when the IVR die 32 is connected to RC component 50. It is observed the transient overshoot represented by line 102 has much higher magnitude than the transient overshoot represented by line 104, and lasts longer. The transient overshoot may cause the damage to the powered devices and thus cause serious reliability issues. Accordingly, the package in accordance with the embodiments of the present disclosure is more reliable.

In addition, as shown in FIGS. 19 and 20, inductors LP1 and LP2 represent the parasitic inductance of the metal lines in the conduction paths 98 (FIG. 9). By inserting the RC component 50 in the path between the IVR die 32 and package component 84 (which is represented as the load resistance Rload), the parasitic inductance is also reduced.

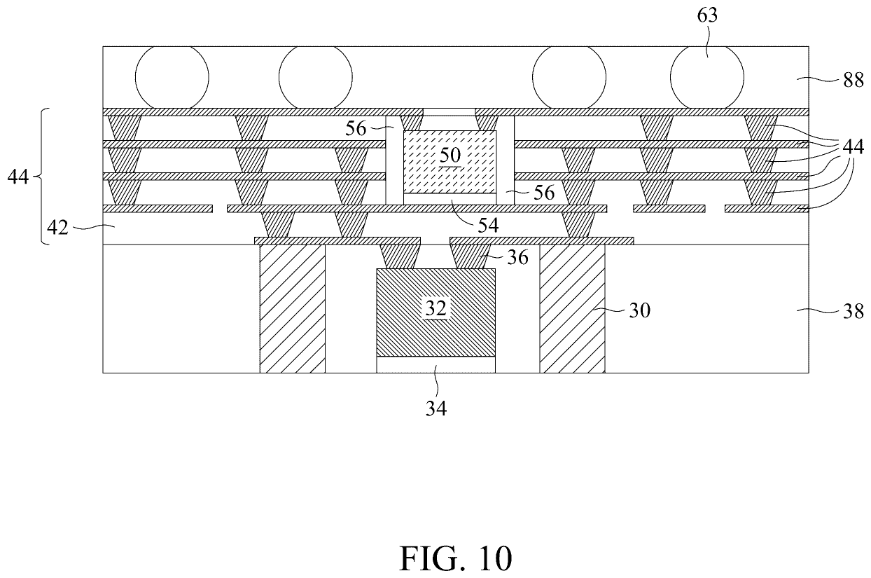

FIG. 10 illustrates an amplified view of a portion of the package 94 in FIG. 9, wherein the illustrated portion includes the IVR die 32 and the RC component 50. The redistribution lines 44 are shown as including metal lines and metal vias interconnecting the metal lines.

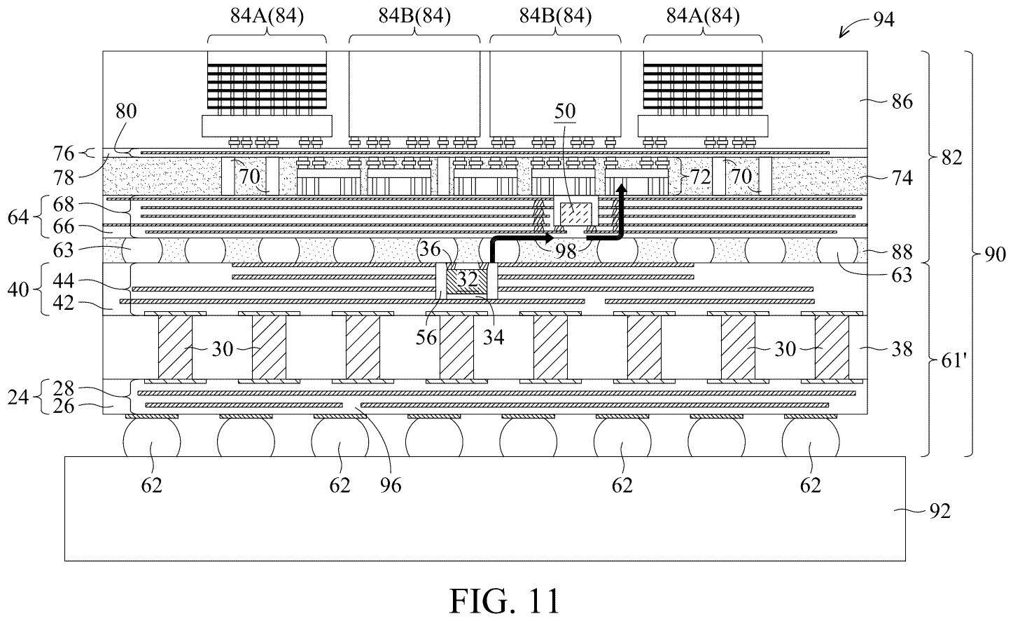

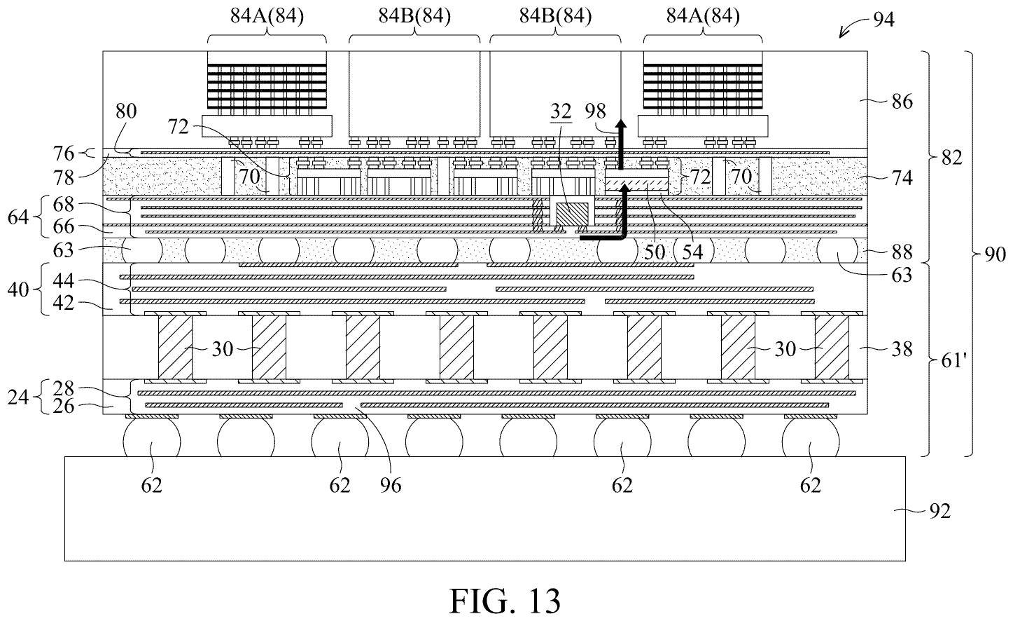

FIG. 11 illustrates a cross-sectional view of package 94 in accordance with alternative embodiments of the present disclosure. Unless specified otherwise, the materials, the structures, and the formation processes of the components in these embodiments (and the subsequent embodiments shown in FIGS. 13-18) are essentially the same as the like components denoted by like reference numerals in the preceding embodiments. The details regarding the materials, the structures, and the formation processes provided in each of the embodiments throughout the description may be applied to any other embodiment whenever applicable, and may not be repeated.

In FIG. 11, IVR die 32, instead of located in dielectric core 38, is located in redistribution structure 40, and may be, or may not be, in contact with dielectric layers 42. The details in the placement of IVR die 32 may be essentially the same as the placement of RC component 50 as shown in FIGS. 5 and 6, and the details are not repeated herein. IVR die 32 may be encapsulated in encapsulant 56, or may tightly fit in the opening in redistribution structure 40, and thus in physical contact with dielectric layers 42. IVR die 32 may or may not be in physical contact with redistribution lines 44.

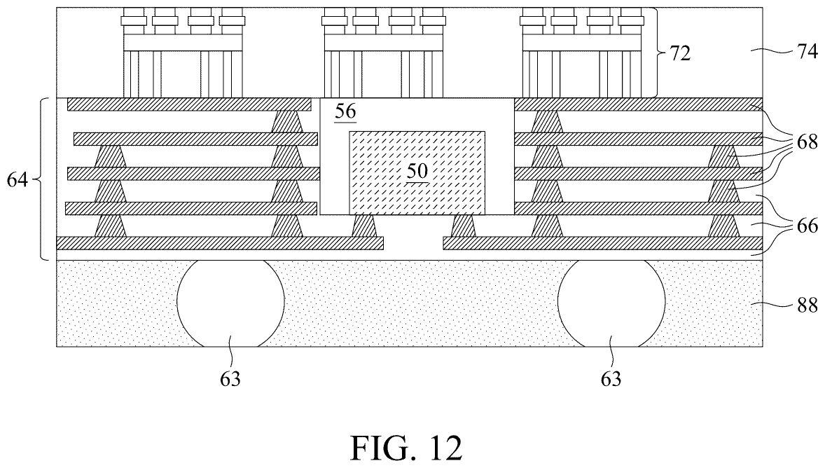

RC component 50 is located in redistribution structure 64. In accordance with some embodiments, after the formation of redistribution structure 64, an opening is formed in redistribution structure 64, and RC component 50 is placed in the opening, and flip-bonded to redistribution lines 68. An encapsulant such as an underfill 56 (not shown in FIG. 11, refer to FIG. 12) is then dispensed to encapsulate RC component 50. Underfill 56 may have some portion directly over RC component 50, as shown in FIG. 12, or may be removed from the regions directly over RC component 50.

As shown by the voltage conduction paths 98, the RC component 50 is also inserted into the path for conducting the voltage output from IVR die 32 to package component 84, and hence may reduce the transient overshoot.

FIG. 12 illustrates an amplified view of a portion of the package 94 in FIG. 11, wherein the illustrated portion includes the RC component 50. The redistribution lines 68 are shown as including metal lines and metal vias interconnecting the metal lines.

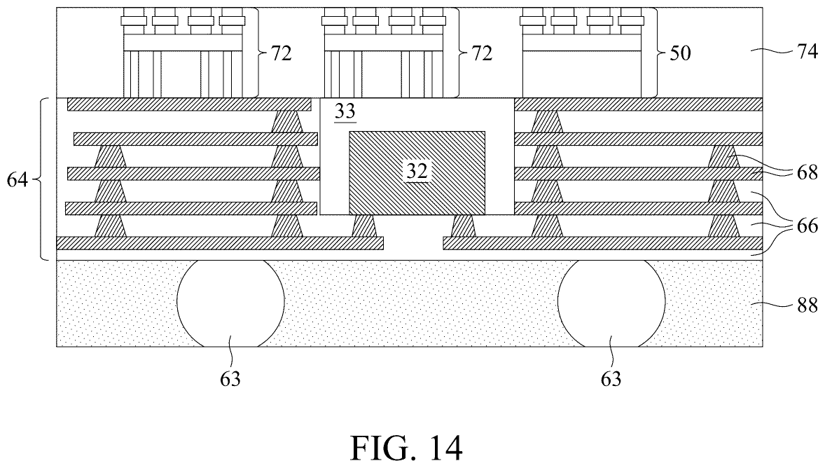

FIG. 13 illustrates a cross-sectional view of package 94 in accordance with alternative embodiments of the present disclosure. IVR die 32 is located in redistribution structure 64, and may be, or may not be in contact with dielectric layers 66. The details in the placement of IVR die 32 may be essentially the same as the placement of RC component 50 as shown in FIGS. 5 and 6, and the details are not repeated herein. IVR die 32 may be encapsulated in encapsulant 56 (FIG. 14), or may tightly fit in the opening in redistribution structure 64, and thus in physical contact with dielectric layers 66. IVR die 32 may or may not be in physical contact with redistribution lines 68. IVR die 32 may be flip-bonded to redistribution lines 68 in accordance with some embodiments.

RC component 50 is located in encapsulant 74. In accordance with some embodiments, RC component 50 is placed over redistribution structure 64 (for example, through die-attach film 54), followed by encapsulating the RC component 50, device dies 72, and through-vias 70 in encapsulant 74. As shown by the voltage conduction path 98, the RC component 50 is also in the path for conducting the voltage output from IVR die 32 to package components 94, and hence may reduce the transient overshoot.

FIG. 14 illustrates an amplified view of a portion of the package 94 in FIG. 13, wherein the illustrated portion includes the IVR die 32 and the RC component 50. In accordance with some embodiments, IVR die 32 is encircled by encapsulant (such as an underfill) 33. Underfill 33 may have a portion directly over IVR die 32 as shown in FIG. 14. Alternatively, underfill 33 does not have any portion directly over IVR die 32.

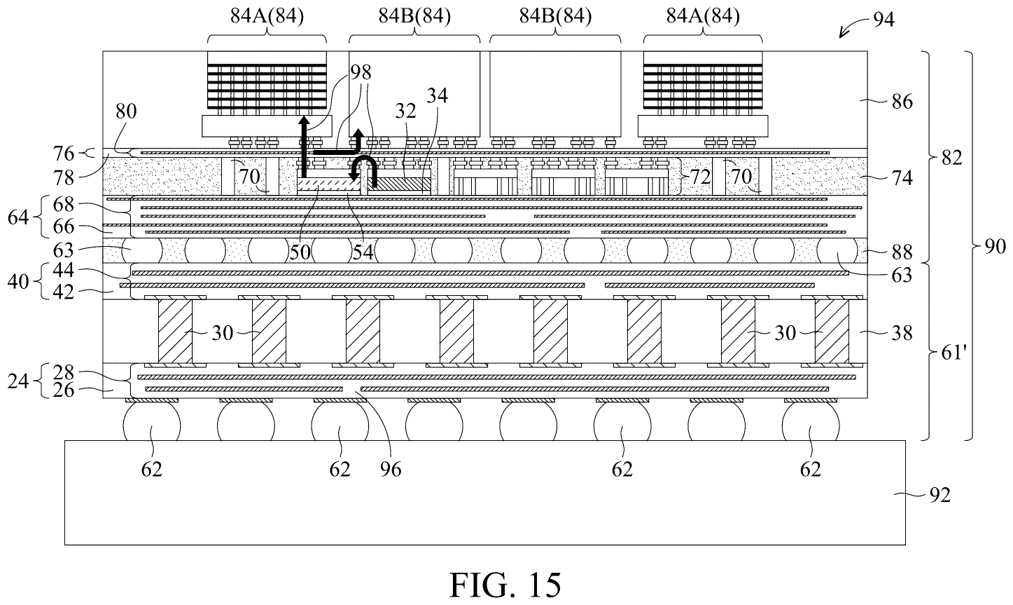

FIG. 15 illustrates a cross-sectional view of package 94 in accordance with alternative embodiments of the present disclosure. Both of IVR die 32 and RC component 50 are located in encapsulant 74, and are at the same level as device dies 70, which may include LSI dies 70. As shown by the voltage conduction path 98, the RC component 50 is also essentially in the path for conducting the voltage output from IVR die 32 to package components 90, and hence may reduce the transient overshoot.

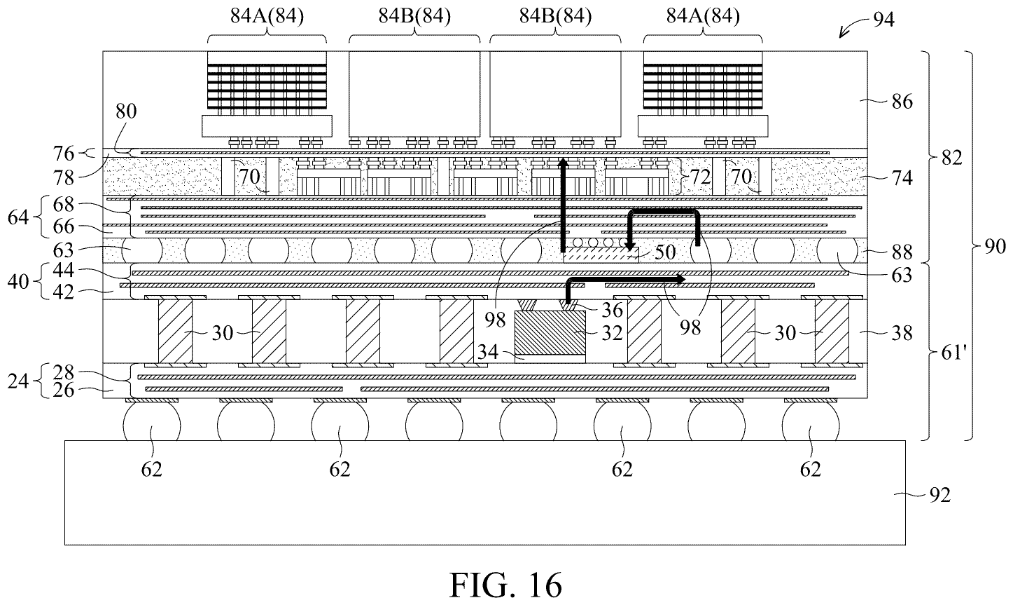

FIG. 16 illustrates a cross-sectional view of package 94 in accordance with alternative embodiments of the present disclosure. IVR die 32 is located in dielectric core 38, which is essentially the same as shown in FIG. 9. The details in the placement of IVR die 32 may be essentially the same as the what are shown in FIGS. 2 and 3, and the details are not repeated herein.

RC component 50 is located in underfill 88 in accordance with these embodiments. RC component 50 may be bonded to redistribution structure 64 before package component 82 is bonded to package substrate 61′. As shown by the voltage conduction path 98, the RC component 50 is also in the path for conducting the voltage output from IVR die 32 to package components 84, and hence may reduce the transient overshoot.

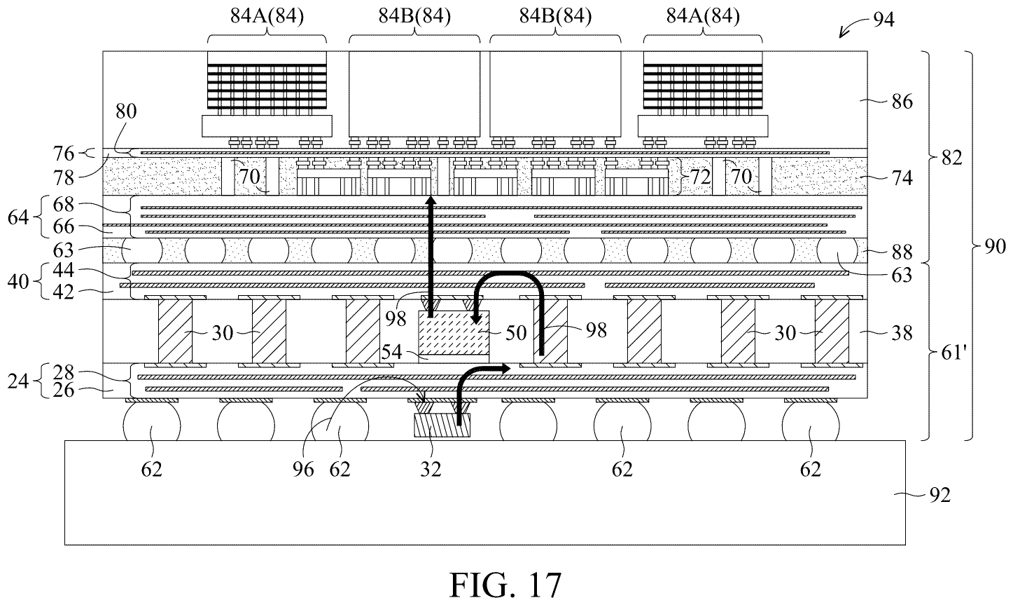

FIG. 17 illustrates a cross-sectional view of package 94 in accordance with alternative embodiments of the present disclosure. RC component 50 is located in dielectric core 38. The placement of RC component 50 may be essentially the same as the placement of IVR die 32 as shown in FIGS. 2 and 3, and the details are not repeated herein.

IVR die 32 is bonded to the bottom of package substrate 61′, and may be encapsulated in a underfill that is filled into the gap between package substrate 61′ and package component 92. As shown by the voltage conduction path 98, the RC component 50 is also in the path for conducting the voltage output from IVR die 32 to package components 84, and hence may reduce the transient overshoot.

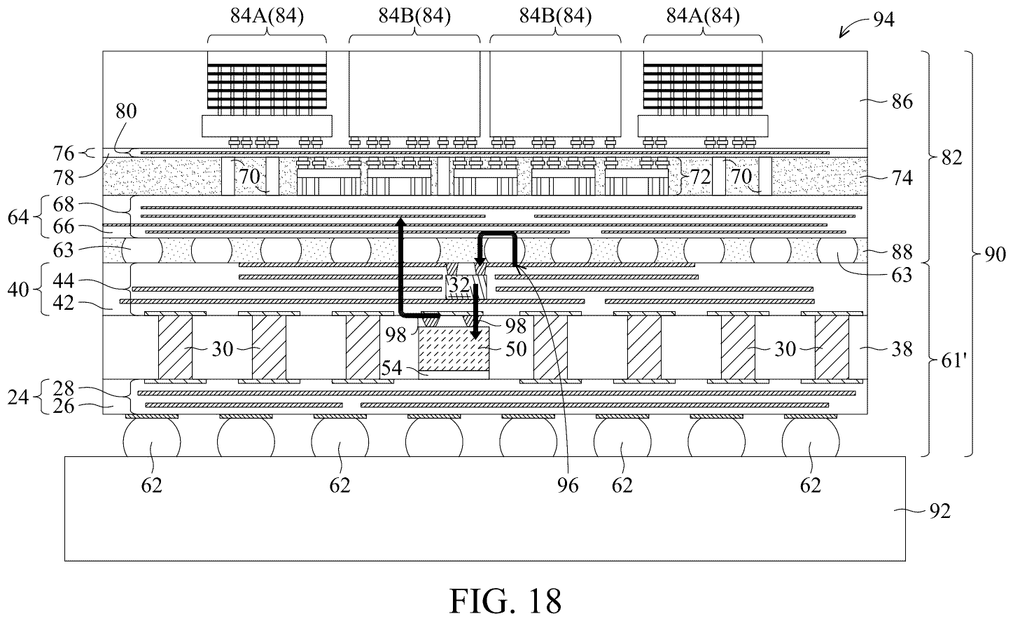

FIG. 18 illustrates a cross-sectional view of package 94 in accordance with alternative embodiments of the present disclosure. RC component 50 is located in dielectric core 38, which is essentially the same as shown in FIG. 17. The details in the placement of RC component 50 may be essentially the same as the placement of IVR die 32 as in FIGS. 2 and 3, and the details are not repeated herein.

IVR die 32, on the other hand, is above the RC component 50. In accordance with some embodiments, IVR die 32 is placed in redistribution structure 40, and may or may not be in an underfill. The details of placing IVR die 32 may be essentially the same as the placement of RC component 50 as shown in FIGS. 5 and 6, and the details are not repeated herein.

As shown by the voltage conduction path 98, although the RC component 50 is underlying the IVR die 32, and thus the path for conducting the output voltage from IVR die 32 to package components 84 is increased, this embodiment has increased design flexibility, and the IVR die 32 and RC component 50 have the flexibility of being placed where feature density is low and more space is available. The increase in the conduction path is minimal.

In above-illustrated embodiments, some processes and features are discussed in accordance with some embodiments of the present disclosure to form a three-dimensional (3D) package. Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

The embodiments of the present disclosure have some advantageous features. By inserting a RC component into the conduction path between an IVR die and powered devices, voltage transient overshoot may be reduced. There is minimal increase in the parasitic inductance since the RC component is in the voltage conduction path.

In accordance with some embodiments of the present disclosure, a method comprises placing an integrated voltage regulator in a first package component; placing a RC component in a second package component; electrically connecting the RC component to the integrated voltage regulator; and electrically connecting a first device die to the RC component, wherein the RC component is in an electrical path that connects the integrated voltage regulator to the first device die. In an embodiment, the RC component is over the integrated voltage regulator, and wherein the first device die is further located over the integrated voltage regulator.

In an embodiment, the method further comprises forming a first redistribution structure, wherein the integrated voltage regulator is placed over the first redistribution structure; encapsulating the integrated voltage regulator in a dielectric core, wherein the first redistribution structure and the dielectric core collectively for the first package component; and forming a second redistribution structure as the second package component that is over and electrically coupling to the integrated voltage regulator, wherein the first redistribution structure, the encapsulant, and the second redistribution structure collectively form a package substrate.

In an embodiment, the integrated voltage regulator is adhered to the first redistribution structure through a die-attach film, and wherein the integrated voltage regulator is electrically connected to the RC component through the second redistribution structure. In an embodiment, the RC component is placed in the second redistribution structure. In an embodiment, the forming the second redistribution structure comprises forming a plurality of dielectric layers and a plurality of redistribution lines in the plurality of dielectric layers, and the method further comprises forming an opening in the plurality of dielectric layers, wherein the RC component is placed in the opening.

In an embodiment, the method further comprises disposing an encapsulant into the opening to encapsulate the RC component therein. In an embodiment, the method further comprises forming a redistribution structure comprising forming a plurality of dielectric layers and a plurality of redistribution lines in the plurality of dielectric layers; and forming an opening in the plurality of dielectric layers, wherein the integrated voltage regulator is placed in the opening. In an embodiment, the method further comprises disposing an encapsulant into the opening to encapsulate the integrated voltage regulator therein.

In an embodiment, the method further comprises bonding a local silicon interconnect die over the RC component; and bonding a second device die over the local silicon interconnect die, wherein the local silicon interconnect die is configured to electrically bridge the first device die to the second device die.

In accordance with some embodiments of the present disclosure, a structure comprises an integrated voltage regulator; a RC component over and electrically coupling to the integrated voltage regulator; a first device die over the integrated voltage regulator and the RC component; a first electrical connection path connecting the integrated voltage regulator to an input of the RC component; and a second electrical connection path connecting an output of the RC component to the first device die. In an embodiment, the structure further comprises a package substrate, wherein both of the integrated voltage regulator and the RC component are embedded in the package substrate.

In an embodiment, the package substrate comprises a first redistribution structure; a dielectric core over the first redistribution structure, wherein the integrated voltage regulator is in the dielectric core; and a second redistribution structure over the dielectric core, wherein the RC component is in the second redistribution structure.

In an embodiment, the structure further comprises a package substrate comprising a first redistribution structure, wherein the integrated voltage regulator is attached to a bottom surface of the first redistribution structure; a dielectric core over the first redistribution structure, wherein the RC component is in the dielectric core; and a second redistribution structure over the dielectric core and the RC component.

In an embodiment, the RC component comprises a plurality of RC units, each comprising a resistor and a capacitor connected to the resistor. In an embodiment, the RC component is a single-RC component that comprises a resistor and a capacitor connected to the resistor.

In accordance with some embodiments of the present disclosure, a structure comprises a package substrate comprising a first redistribution structure; a dielectric core over the first redistribution structure; a second redistribution structure over the dielectric core; a plurality of through-vias in the dielectric core and electrically connecting the first redistribution structure to the second redistribution structure; an integrated voltage regulator in the dielectric core; and a RC component over and electrically connected to the integrated voltage regulator; and a package component over and bonding to the package substrate, wherein the package component comprises a device die electrically connected to the RC component.

In an embodiment, the RC component is in the second redistribution structure. In an embodiment, the second redistribution structure comprises a plurality of dielectric layers, wherein the RC component is in the plurality of dielectric layers; and a plurality of redistribution lines in the plurality of dielectric layers. In an embodiment, the structure further comprises an underfill in the plurality of dielectric layers, wherein the RC component is further in the underfill.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A method comprising:
placing an integrated voltage regulator in a first package component;
placing a RC component in a second package component;
electrically connecting the RC component to the integrated voltage regulator; and
electrically connecting a first device die to the RC component, wherein the RC component is in an electrical path that connects the integrated voltage regulator to the first device die.

2. The method of claim 1, wherein the RC component is over the integrated voltage regulator, and wherein the first device die is further located over the integrated voltage regulator.

3. The method of claim 1, further comprising:
forming a first redistribution structure, wherein the integrated voltage regulator is placed over the first redistribution structure;
encapsulating the integrated voltage regulator in a dielectric core, wherein the first redistribution structure and the dielectric core collectively for the first package component; and
forming a second redistribution structure as the second package component that is over and electrically coupling to the integrated voltage regulator, wherein the first redistribution structure, an encapsulant, and the second redistribution structure collectively form a package substrate.

4. The method of claim 3, wherein the integrated voltage regulator is adhered to the first redistribution structure through a die-attach film, and wherein the integrated voltage regulator is electrically connected to the RC component through the second redistribution structure.

5. The method of claim 3, wherein the RC component is placed in the second redistribution structure.

6. The method of claim 3, wherein the forming the second redistribution structure comprises forming a plurality of dielectric layers and a plurality of redistribution lines in the plurality of dielectric layers, and the method further comprises:
forming an opening in the plurality of dielectric layers, wherein the RC component is placed in the opening.

7. The method of claim 6, further comprising disposing the encapsulant into the opening to encapsulate the RC component therein.

8. The method of claim 1, further comprising:
forming a redistribution structure comprising forming a plurality of dielectric layers and a plurality of redistribution lines in the plurality of dielectric layers; and
forming an opening in the plurality of dielectric layers, wherein the integrated voltage regulator is placed in the opening.

9. The method of claim 8, further comprising disposing an encapsulant into the opening to encapsulate the integrated voltage regulator therein.

10. The method of claim 1, further comprising:
bonding a local silicon interconnect die over the RC component; and
bonding a second device die over the local silicon interconnect die, wherein the local silicon interconnect die is configured to electrically bridge the first device die to the second device die.

11. A structure comprising:
an integrated voltage regulator;
a RC component over and electrically coupling to the integrated voltage regulator;
a first device die over the integrated voltage regulator and the RC component;
a first electrical connection path connecting the integrated voltage regulator to an input of the RC component; and
a second electrical connection path connecting an output of the RC component to the first device die.

12. The structure of claim 11, further comprising a package substrate, wherein both of the integrated voltage regulator and the RC component are embedded in the package substrate.

13. The structure of claim 12, wherein the package substrate comprises:
a first redistribution structure;
a dielectric core over the first redistribution structure, wherein the integrated voltage regulator is in the dielectric core; and
a second redistribution structure over the dielectric core, wherein the RC component is in the second redistribution structure.

14. The structure of claim 11, further comprising a package substrate comprising:
a first redistribution structure, wherein the integrated voltage regulator is attached to a bottom surface of the first redistribution structure;
a dielectric core over the first redistribution structure, wherein the RC component is in the dielectric core; and
a second redistribution structure over the dielectric core and the RC component.

15. The structure of claim 11, wherein the RC component comprises a plurality of RC units, each comprising a resistor and a capacitor connected to the resistor.

16. The structure of claim 11, wherein the RC component is a single-RC component that comprises a resistor and a capacitor connected to the resistor.

17. A structure comprising:
a package substrate comprising:
a first redistribution structure;
a dielectric core over the first redistribution structure;
a second redistribution structure over the dielectric core;
a plurality of through-vias in the dielectric core and electrically connecting the first redistribution structure to the second redistribution structure;
an integrated voltage regulator in the dielectric core; and
a RC component over and electrically connected to the integrated voltage regulator; and
a package component over and bonding to the package substrate, wherein the package component comprises a device die electrically connected to the RC component.

18. The structure of claim 17, wherein the RC component is in the second redistribution structure.

19. The structure of claim 17, wherein the second redistribution structure comprises:
a plurality of dielectric layers, wherein the RC component is in the plurality of dielectric layers; and
a plurality of redistribution lines in the plurality of dielectric layers.

20. The structure of claim 19, further comprising an underfill in the plurality of dielectric layers, wherein the RC component is further in the underfill.
